(19) United States
(12) Patent Application Publication
(10) Pub. No.: US 2016/0247860 A1
(43) Pub. Date: Aug. 25, 2016

(54) SOLID-STATE IMAGE SENSING DEVICE

(71) Applicant: KABUSHIKI KAISHA TOSHIBA, Tokyo (JP)

(72) Inventors: Machiko ITO, Yokohama (JP); Isao Takasu, Tokyo (JP); Atsushi Wada, Kawasaki (JP); Yoshinori Iida, Tokyo (JP)

(73) Assignee: KABUSHIKI KAISHA TOSHIBA, Tokyo (JP)

(21) Appl. No.: 15/048,373

(22) Filed: Feb. 19, 2016

(30) Foreign Application Priority Data
Feb. 23, 2015 (JP) 2015-033097

(51) Int. Cl. H01L 27/30; H01L 51/44; H01L 51/42

(52) U.S. Cl. CPC H01L 27/307; H01L 51/424; H01L 51/44

(57) ABSTRACT

According to one embodiment, a solid-state image sensing device includes an organic photoelectric conversion layer. The organic photoelectric conversion layer includes an organic semiconductor material and an organic dye. The organic semiconductor material selectively absorbs light having one of three primary colors selected from blue light, green light, and red light. The organic semiconductor material allows the other two of primary colors of light to be transmitted therethrough. The organic dye is dispersed in the organic semiconductor material. The organic dye receives energy less than excitation energy of the organic semiconductor material.

### CROSS-REFERENCE TO RELATED APPLICATION

This application is based upon and claims the benefit of priority from Japanese Patent Application No. 2015-033097, filed Feb. 23, 2015; the entire contents of which are incorporated herein by reference.

### FIELD

Embodiments described herein relate generally to a solid-state image sensing device.

### BACKGROUND

Solid-state image sensing devices are widely used in various fields in, for example, digital cameras, mobile terminals such as portable telephones (including smartphones), monitoring cameras, web cameras utilizing the internet, and the like. In such solid-state image sensing devices, in order to realize all of high image quality, downsizing, and weight saving, image-sensing devices are proposed which uses an organic photoelectric conversion layer in a photoelectric converter.

### BRIEF DESCRIPTION OF THE DRAWINGS

FIG. 1 is a cross-sectional view schematically showing the configuration of a solid-state image sensing device according to a first embodiment.

FIG. 2 is a cross-sectional view schematically showing a relevant part of the configuration of the solid-state image sensing device according to the first embodiment.

FIG. 3 is a cross-sectional view schematically showing a relevant part the configuration of the solid-state image sensing device according to the first embodiment.

FIG. 4 is a perspective view showing an example of a CMOS image sensor to which the solid-state image sensing device according to the first embodiment is applied.

FIG. 5 is a perspective view showing another example of a CMOS image sensor to which the solid-state image sensing device according to the first embodiment is applied.

FIG. 6 is a plan view showing a smartphone serving as an imaging device provided with a CMOS image sensor built therein.

FIG. 7 is a plan view showing a tablet terminal device serving as an imaging device provided with a CMOS image sensor built therein.

FIG. 8 is a plan view showing an example of an automobile provided with a car-mounted camera and an on-board image display device.

FIG. 9 is a plan view showing another example of an automobile provided with a car-mounted camera and an on-board image display device.

FIG. 10 is a cross-sectional view schematically showing the configuration of a solid-state image sensing device according to a second embodiment.

FIG. 11 is a schematic cross-sectional view showing a configuration of a photoelectric conversion device including a green-light organic photoelectric conversion layer and a red-light organic photoelectric conversion layer which are adjacent to each other.

### DETAILED DESCRIPTION

Hereinafter, a solid-state image sensing device according to the embodiment will be described with reference to drawings.

In the drawings used in the below description, in order for the respective components to be of understandable size in the drawings, the dimensions and the proportions of the components are modified as needed compared with the real components.

### First Embodiment

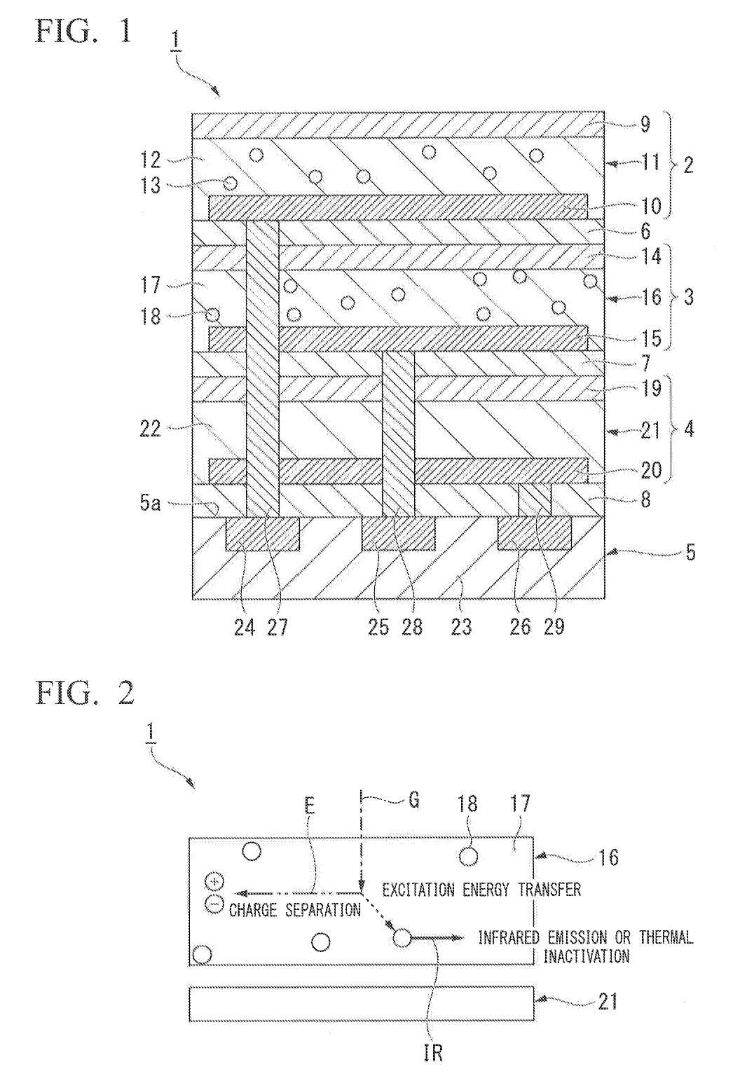

FIG. 1 is a cross-sectional view schematically showing the configuration of a solid-state image sensing device according to a first embodiment. As shown in FIG. 1, the solid-state image sensing device 1 according to the embodiment includes a blue-light photoelectric converter 2 (first photoelectric converter), a green-light photoelectric converter 3 (second photoelectric converter), a red-light photoelectric converter 4 (third photoelectric converter), and a substrate 5. Particularly, FIG. 1 only shows one pixel of the solid-state image sensing device 1 according to the embodiment including a vertical layered structure in which the photoelectric converters 2, 3, and 4 used for the respective colors are sequentially stacked in layers in the thickness direction on one surface 5a of the substrate 5 with insulating layers 6, 7, and 8 interposed therebetween; and the description regarding the other components thereof is omitted.

The blue-light photoelectric converter 2 includes an upper transparent electrode 9 (may be referred to as a transparent counter electrode), a lower transparent electrode 10 (may be referred to as a base electrode or a pixel electrode), and a blue-light organic photoelectric conversion layer 11 (first organic photoelectric conversion layer). The blue-light photoelectric converter 2 is provided so that the blue-light organic photoelectric conversion layer 11 is sandwiched between the paired transparent electrodes 9 and 10.

The upper transparent electrode 9 is used to apply a bias voltage supplied from the outside thereof to the blue-light organic photoelectric conversion layer 11. The upper transparent electrode 9 is provided so as to cover the surface which is located on the opposite side of the substrate 5 and serves as a light-receiving face of the blue-light organic photoelectric conversion layer 11. As long as a material used to form the upper transparent electrode 9 is a transparent electroconductive material, it is not particularly limited. As such transparent electroconductive material, specifically, for example, indium tin oxide (ITO) or the like is adopted.

The lower transparent electrode 10 is used to collect an electrical charge that is generated due to photoelectric conversion by the blue-light organic photoelectric conversion layer 1. The lower transparent electrode 10 is provided for each pixel on the surface of the blue-light organic photoelectric conversion layer 11 which faces the substrate 5. As long as a material used to form the lower transparent electrode 10 is a transparent electroconductive material, it is not particularly limited. As such transparent electroconductive material, specifically, for example, indium tin oxide (ITO) or the like is adopted.

The blue-light organic photoelectric conversion layer 11 is an organic photoelectric conversion film including a blue-light organic semiconductor material 12 (first organic semiconductor material) and a first organic dye 13. Of blue light, green light, and red light which are three primary colors of light, the blue-light organic semiconductor material 12 selectively absorbs blue light and allows the other two primary colors of light (i.e., green and red) to be transmitted therethrough. The first organic dye 13 is dispersed in the blue-light organic semiconductor material 12.

Particularly, the blue light of three primary colors of light means light having a wavelength-band of 400 to 500 nm. The green light means light having a wavelength-band of 500 to 600 nm. The red light means light having a wavelength-band of 600 to 700 nm.

Moreover, based on a transmission spectrum and a reflection spectrum of visible light of a photoelectric converter, it is possible to determine whether or not each wavelength of light can be selectively absorbed. Furthermore, based on a spectral sensitivity (photoelectric conversion efficiency with respect to irradiation wavelength) of the photoelectric converter during applying voltage thereto, it is possible to evaluate the wavelength selectivity thereof.

As the blue-light organic semiconductor material 12, specifically, a porphyrincobalt complex, a coumarin derivative, fullerene, derivatives thereof, a florene compound, a pyrazole derivative, or the like, for example, can be adopted. As a material used to form the blue-light organic semiconductor material 12, any one selected from the group consisting of the aforementioned compounds may be used, and a material including two or more selected therefrom may be used.

The first organic dye 13 is an organic dye used to receive a lower level of energy than the excitation energy of the blue-light organic semiconductor material 12. Particularly, the first organic dye is an organic dye which is dispersed in the blue-light organic photoelectric conversion layer 11 (i.e., the blue-light organic semiconductor material 12) and absorbs energy corresponding to that of green light. As the above-described organic dye, specifically, a quinacridone derivative, a perylene bisimide derivative, an oligothiophene derivative, a subphthalocyanine derivative, a rhodamine compound, a ketocyanine derivative, or the like, for example, can be adopted. As a material used to form the first organic dye 13, any one selected from the group consisting of the aforementioned compounds may be used, and a material including two or more selected therefrom may be used together.

As long as the blue-light organic photoelectric conversion layer 11 has a layer thickness which can sufficiently absorb the blue light in the blue-light photoelectric converter 2 when the solid-state image sensing device 1 receives light, the thickness thereof is not particularly limited. Specifically, for example, it is only necessary that the thickness be in a range of 30 to 300 nm, and a range of 50 to 200 nm is preferable.

In the blue-light organic photoelectric conversion layer 11, it is preferable that the mass content of the first organic dye 13 be lower than the mass content of the blue-light organic semiconductor material 12. Particularly, it is preferable that the contained amount (concentration) of the first organic dye 13 contained in the blue-light organic photoelectric conversion layer 11 be 0.75/(N_{A}·R³)(mol/m³) where an energy transfer radius of the blue-light organic semiconductor material 12 is defined as R (m) and Avogadro's constant is defined as N_{A} (mol⁻¹).

Here, the energy transfer radius R of the organic semiconductor material can be determined by the following Formula (1).

(Formula 1)

R=0.2108[κ²φₐn⁻⁴∫fₐ(λ)ε_{b}(λ)λ⁴dλ]^{1/6} (1)

In the above-mentioned Formula (1), κ represents an orientation factor and is a value determined from an angle between the transition dipole moment of a donor transmitting energy and an acceptor (organic dye) receiving energy. The φₐ represents a radiative quantum yield when energy transfer is not present. The n represents a refractive index of a medium. The fₐ represents a shape function of an emission spectrum of a donor, and the ε_{b} represents the molar absorptivity of the acceptor (organic dye).

The contained amount of the first organic dye 13 in the blue-light organic photoelectric conversion layer 11 may very due to measurement of the aforementioned energy transfer radius R of the organic semiconductor material; and it is preferable that the upper limit thereof be lower than or equal to 46/(ε_{b}·L) (mol/m³) (Σ_{b}: molar absorptivity of an organic dye, L: film thickness of organic photoelectric conversion layer). As a result of setting the contained amount of the first organic dye 13 in the blue-light organic photoelectric conversion layer 11 to be lower than or equal to the above-mentioned upper limit, it is possible to reduce a transmittance loss (%) due to absorption of an organic dye so as to be within 10% which is substantially the same range as that of color filters.

The mass content of the first organic dye 13 in the blue-light organic photoelectric conversion layer 11 can be calculated by, for example, dissolving the blue-light organic photoelectric conversion layer 11, thereafter carrying out separation thereof by use of high performance liquid chromatography (HPLC) or the like, and then examining the absorbance at each wavelength.

Furthermore, by analyzing the first organic dye 13 in the blue-light organic photoelectric conversion layer 11 in the thickness direction by use of secondary ion mass spectrometry (SIMS), it can be determined that the first organic dye 13 is uniformly distributed in the blue-light organic photoelectric conversion layer 11 without being eccentrically-located in the layer thickness direction thereof.

Regarding the light received by the solid-state image sensing device 1, the blue-light photoelectric converter 2 having the above-described configuration absorbs all of the light (i.e., blue light) having a wavelength corresponding to that of the excitation energy of the blue-light organic semiconductor material 12, the blue-light photoelectric converter absorbs some of the light (i.e., green light) having a wavelength corresponding to a lower level of energy than the excitation energy thereof, and the blue-light photoelectric converter allows the remaining light (remaining portion) to be transmitted therethrough.

The insulating layers 6, 7, and 8 are provided to electrically isolate the photoelectric converters constituting the solid-state image sensing device 1 from the photoelectric converter and from the substrate. Specifically, the insulating layer 6 is provided between the blue-light photoelectric converter 2 and the green-light photoelectric converter 3, the insulating layer 7 is provided between the green-light photoelectric converter 3 and the red-light photoelectric converter 4, and the insulating layer 8 is provided between the red-light photoelectric converter 4 and the substrate 5. As long as a material used to form the insulating layers 6, 7, and 8 has an excellent insulation property and an excellent optical transparency, the material is not particularly limited. As such material, for example, silicon oxide (SiO₂) can be used.

The green-light photoelectric converter 3 includes an upper transparent electrode 14 (transparent counter electrode), a lower transparent electrode 15 (base electrode or a pixel electrode), and a green-light organic photoelectric conversion layer 16 (second organic photoelectric conversion layer). The green-light photoelectric converter 3 is provided so that the green-light organic photoelectric conversion layer 16 is sandwiched between the paired transparent electrodes 14 and 15.

The upper transparent electrode 14 has the same configuration as that of the above-described upper transparent electrode 9, the lower transparent electrode 15 has the same configuration as that of the above-described lower transparent electrode 10, and therefore an explanation thereof will be omitted.

The green-light organic photoelectric conversion layer 16 is an organic photoelectric conversion film including a green-light organic semiconductor material 17 (second organic semiconductor material) and a second organic dye 18. Of blue light, green light, and red light which are three primary colors of light, the green-light organic semiconductor material 17 selectively absorbs green light and allows the other two primary colors (i.e., blue and red) of light to be transmitted therethrough. The second organic dye 18 is dispersed in the green-light organic semiconductor material 17.

As the green-light organic semiconductor material 17, specifically, a quinacridone derivative, a perylene bisimide derivative, an oligothiophene derivative, a subphthalocyanine derivative, a rhodamine compound, a ketocyanine derivative, or the like, for example, can be adopted. As a material used to form the green-light organic semiconductor material 17, any one selected from the group consisting of the aforementioned compounds may be used, and a material including two or more selected therefrom may be used.

The second organic dye 18 is an organic dye used to receive a lower level of energy than the excitation energy of the green-light organic semiconductor material 17. Particularly, the second organic dye is an organic dye which is dispersed in the green-light organic photoelectric conversion layer 16 (i.e., the green-light organic semiconductor material 17) and absorbs energy corresponding to that of red light. As the above-described organic dye, specifically, a phthalocyanine derivative, a squarylium derivative, a subnaphthalocyanine derivative, or the like, for example, can be adopted. As a material used to form the second organic dye 18, any one selected from the group consisting of the aforementioned compounds may be used, and a material including two or more selected therefrom may be used together.

As long as the green-light organic photoelectric conversion layer 16 has a layer thickness which can sufficiently absorb the green light in the green-light photoelectric converter 3 when the solid-state image sensing device 1 receives light, the thickness thereof is not particularly limited. Specifically, for example, it is only necessary that the thickness be in a range of 30 to 300 nm, and a range of 50 to 200 nm is preferable.

In the green-light organic photoelectric conversion layer 16, it is preferable that the mass content of the second organic dye 18 be lower than the mass content of the green-light organic semiconductor material 17. Particularly, it is preferable that the contained amount of the second organic dye 18 in the green-light organic photoelectric conversion layer 16 be 0.75/(N_{A}·R³)(mol/m³) where an energy transfer radius of the green-light organic semiconductor material 17 is defined as R (m) and Avogadro's constant is defined as N_{A} (mol⁻¹).

Particularly, the energy transfer radius R of the organic semiconductor material and the upper limit of the contained amount of the organic dye in the organic photoelectric conversion layer is the same as in the case of the above-mentioned blue-light organic photoelectric conversion layer 11.

The mass content of the second organic dye 18 in the green-light organic photoelectric conversion layer 16 can be calculated by, for example, dissolving the green-light organic photoelectric conversion layer 16, thereafter carrying out separation thereof by use of high performance liquid chromatography (HPLC) or the like, and then examining the absorbance at each wavelength.

Furthermore, by analyzing the second organic dye 18 in the green-light organic photoelectric conversion layer 16 in the thickness direction by use of secondary ion mass spectrometry (SIMS), it can be determined that the second organic dye 18 is uniformly distributed in the green-light organic photoelectric conversion layer 16 without being eccentrically-located in the layer thickness direction thereof.

Regarding the lights (i.e., green light and red light) which are received by the solid-state image sensing device 1 and are passed through the above-described blue-light photoelectric converter 2, the green-light photoelectric converter 3 having the above-described configuration absorbs all of the light (i.e., green light) having a wavelength corresponding to that of the excitation energy of the green-light organic semiconductor material 17, the green-light photoelectric converter absorbs some of the light (i.e., red light) having a wavelength corresponding to a lower level of energy than the excitation energy thereof, and the green-light photoelectric converter allows the remaining light to be transmitted therethrough.

The red-light photoelectric converter 4 includes an upper transparent electrode 19 (transparent counter electrode), a lower transparent electrode 20 (base electrode or a pixel electrode), and a red-light organic photoelectric conversion layer 21 (third organic photoelectric conversion layer). The red-light photoelectric converter 4 is provided so that the red-light organic photoelectric conversion layer 21 is sandwiched between the paired transparent electrodes 19 and 20.

The upper transparent electrode 19 has the same configuration as that of the above-described upper transparent electrodes 9 and 14, the lower transparent electrode 20 has the same configuration as that of the above-described lower transparent electrodes 10 and 15, and therefore an explanation thereof will be omitted.

The red-light organic photoelectric conversion layer 21 is an organic photoelectric conversion film including a red-light organic semiconductor material 22 (third organic semiconductor material). Of blue light, green light, and red light which are three primary colors of light, the red-light organic semiconductor material 22 selectively absorbs red light and allows the other two primary colors of light (i.e., blue and green) to be transmitted therethrough.

As the red-light organic semiconductor material 22, specifically, a phthalocyanine derivative, a squarylium derivative, a subnaphthalocyanine derivative or the like, for example, can be adopted. As a material used to form the red-light organic semiconductor material 22, any one selected from the group consisting of the aforementioned compounds may be used, and a material including two or more selected therefrom may be used.

As long as the red-light organic photoelectric conversion layer 21 has a layer thickness which can sufficiently absorb the red light in the red-light photoelectric converter 4 when the solid-state image sensing device 1 receives light, the thickness thereof is not particularly limited. Specifically, for example, it is only necessary that the thickness be in a range of 30 to 300 nm, and a range of 50 to 200 nm is preferable.

The red-light photoelectric converter 4 having the above-described configuration absorbs the red light that is received by the solid-state image sensing device 1 and passes through the aforementioned blue-light photoelectric converter 2 and the green-light photoelectric converter 3.

The substrate 5 includes a semiconductor substrate 23, a charge storage diodes 24, 25, and 26 (hereinbelow, referred to as “SI)”), contact plugs 27, 28, and 29, and charge transfer lines (for example, CCD system or CMOS system; not shown in the figure) used for reading out a signal charge.

The semiconductor substrate 23 is a substrate having a reduced thickness and has a top surface and a back surface which are flat. The semiconductor substrate 23 is not particularly limited to this, for example, a P-type single-crystalline silicon substrate can be used. Hereinafter, the case of using a P-type single-crystalline silicon substrate as the semiconductor substrate 23 will be described an example.

The SDs 24, 25, and 26 are provided so that one ends thereof are exposed at the top surface of the semiconductor substrate 23 and the other ends are directed toward the inside of the semiconductor substrate 23. That is, one end of each of the SDs 24, 25, and 26 is exposed at the top surface of the semiconductor substrate 23, and the other end of each of the SDs 24, 25, and 26 is directed toward the inside of the semiconductor substrate 23. Additionally, the SDs 24, 25, and 26 are provided in the semiconductor substrate 23 so as to be separated from each other. As the SDs 24, 25, and 26, for example, a high concentration N-type impurity diffusion region can be used.

Particularly, the SD 24 is electrically connected through the contact plug 27 to the lower transparent electrode 10 forming the blue-light photoelectric converter 2. The SD 24 has a function of cumulatively storing an electrical charge that is generated from the blue-light organic photoelectric conversion layer 11 sandwiched between the upper transparent electrode 9 and the lower transparent electrode 10. That is, the SD 24 cumulatively stores an electrical charge corresponding to the blue light that is received by the blue-light organic photoelectric conversion layer 11.

Moreover, the SD 25 is electrically connected through the contact plug 28 to the lower transparent electrode 15 forming the green-light photoelectric converter 3. The SD 25 has a function of cumulatively storing an electrical charge that is generated from the green-light organic photoelectric conversion layer 16 sandwiched between the upper transparent electrode 14 and the lower transparent electrode 15. That is, the SD 25 cumulatively stores an electrical charge corresponding to the green light that is received by the green-light organic photoelectric conversion layer 16.

Moreover, the SD 26 is electrically connected through the contact plug 29 to the lower transparent electrode 20 forming the red-light photoelectric converter 4. The SD 26 has a function of cumulatively storing an electrical charge that is generated from the red-light organic photoelectric conversion layer 21 sandwiched between the upper transparent electrode 19 and the lower transparent electrode 20. That is, the SD 26 cumulatively stores an electrical charge corresponding to the red light that is received by the red-light organic photoelectric conversion layer 21.

One ends of the contact plugs 27, 28, and 29 are in contact with the SDs 24, 25, and 26, respectively, and the other ends of the contact plugs 27, 28, and 29 are in contact with the lower transparent electrodes 10, 15, and 20, respectively. Consequently, the contact plugs 27, 28, and 29 are electrically connected to the SDs 24, 25, and 26 and the lower transparent electrodes 10, 15, and 20, respectively. As the contact plugs 27, 28, and 29, for example, a metal material or a high concentration N-type impurity diffusion region can be used.

Next, a method of manufacturing the solid-state image sensing device 1 according to the embodiment will be described.

First of all, a P-type single-crystalline silicon substrate is prepared as a semiconductor substrate which is not thinned.

Subsequently, the SDs 24, 25, and 26 are formed by well-known methods. Specifically, the semiconductor substrate is subjected to ion implantation with N-type impurities (for example, phosphorus), and thereafter the SDs 24, 25, and 26 are thereby formed by annealing. Next, a multilayer wiring structure (not shown in the figure) including a gate insulator film, an insulating film, wiring, and via holes; and transmission transistors (not shown in the figure) are sequentially formed on the top surface of the semiconductor substrate by well-known methods. After that, the semiconductor substrate is thinned so that the SDs 24, 25, and 26 are exposed at the top surface thereof by well-known methods, and the substrate 5 is thereby formed.

Subsequently, an insulating film is formed on one surface 5a of the substrate 5 by well-known methods. Subsequently, openings are formed on the insulating film so that the surface of the SD 26 is exposed thereto by well-known methods, the openings are filled with an electroconductive material, thereafter the formed layer is subjected to planarization, and the insulating layer 8 and the contact plug 29 are thereby formed.

After that, after a transparent-electroconductive film such as ITO is formed on the insulating layer 8 by well-known methods, the transparent-electroconductive film is patterned so as to have a predetermined pixel size, and the lower transparent electrode 20 is thereby formed. Next, after an organic photoelectric conversion film made of the red-light organic semiconductor material 22 is formed by well-known methods such as a vapor-deposition method so as to implant the lower transparent electrode 20 thereinto, the formed layer is subjected to planarization, and the red-light organic photoelectric conversion layer 21 is thereby formed. Subsequently, a transparent-electroconductive film such as ITO is formed on the red-light organic photoelectric conversion layer 21 by well-known methods, the formed layer is subjected to planarization, and the upper transparent electrode 19 is thereby formed.

After that, an insulating film is formed by well-known methods so as to cover the top surface of the upper transparent electrode 19. Next, by well-known methods, through hole are formed on the insulating film so that the surface of the SD 25 is exposed thereto, the through holes are filled with an electroconductive material, thereafter the formed layer is subjected to planarization, and the insulating layer 7 and the contact plug 28 are thereby formed.

After that, after a transparent-electroconductive film such as ITO is formed on the insulating layer 7 by well-known methods, the transparent-electroconductive film is patterned so as to have a predetermined pixel size, and the lower transparent electrode 15 is thereby formed. Next, after an organic photoelectric conversion film made of the green-light organic semiconductor material 17 and the second organic dye 18 is formed by well-known methods such as a vapor-deposition method (a multi-source deposition method) so as to implant the lower transparent electrode 15 thereinto, the formed layer is subjected to planarization, and the green-light organic photoelectric conversion layer 16 is thereby formed. Subsequently, a transparent-electroconductive film such as ITO is formed on the green-light organic photoelectric conversion layer 16 by well-known methods, the formed layer is subjected to planarization, and the upper transparent electrode 14 is thereby formed.

The method of forming the organic photoelectric conversion film is not particularly limited to this. Not only the above-mentioned vapor-deposition method but also a method of applying a solution containing an organic semiconductor material and an organic dye which are mixed therein at a required ratio of concentration, particularly, for example, a spin coating method, various printing methods (offset printing, inkjet printing, or the like) is adopted as a method of forming an organic photoelectric conversion film.

After that, an insulating film is formed by well-known methods so as to cover the top surface of the upper transparent electrode 14. Next, by well-known methods, through hole are formed on the insulating film so that the surface of the SD 24 is exposed thereto, the through holes are filled with an electroconductive material, thereafter the formed layer is subjected to planarization, and the insulating layer 6 and the contact plug 27 are thereby formed.

After that, after a transparent-electroconductive film such as ITO is formed on the insulating layer 6 by well-known methods, the transparent-electroconductive film is patterned so as to have a predetermined pixel size, and the lower transparent electrode 10 is thereby formed. Next, after an organic photoelectric conversion film made of the blue-light organic semiconductor material 12 and the first organic dye 13 is formed by well-known methods such as a vapor-deposition method (a multi-source deposition method) or various solution application methods so as to implant the lower transparent electrode 10 thereinto, the formed layer is subjected to planarization, and the blue-light organic photoelectric conversion layer 11 is thereby formed. Subsequently, a transparent-electroconductive film such as ITO is formed on the blue-light organic photoelectric conversion layer 11 by well-known methods, the formed layer is subjected to planarization, and the upper transparent electrode 9 is thereby formed.

As a result of carrying out the above-described step, it is possible to manufacture, on the substrate 5, the solid-state image sensing device 1 according to the embodiment in which the photoelectric converters corresponding to the three primary colors of light are stacked in layers.

Next, an action of the solid-state image sensing device 1 according to the embodiment will be described.

In the solid-state image sensing device 1 according to the embodiment, of the light received by the solid-state image sensing device, blue light is only absorbed by the blue-light organic photoelectric conversion layer 11 and is photoelectrically converted into power. Specifically, a bias voltage is applied between the paired transparent electrodes 9 and 10 in the blue-light photoelectric converter 2. Subsequently, the blue-light organic photoelectric conversion layer 11 absorbs blue light and photoelectrically converts the light into power, and an electrical charge is generated therefrom. At this time, the amount of the generated electrical charge varies depending on the intensity of the light incident to the organic photoelectric conversion layer. The generated electrical charge is accumulated in the SD 24.

Next, regarding the light that is passed through the blue-light organic photoelectric conversion layer 11, green light is only absorbed by the green-light organic photoelectric conversion layer 16 and is photoelectrically converted into power. Furthermore, of the light that is passed through the blue-light organic photoelectric conversion layer 11 and the green-light organic photoelectric conversion layer 16, red light is only absorbed by the red-light organic photoelectric conversion layer 21 and is photoelectrically converted into power. At this time, the amount of the generated electrical charge varies depending on the intensity of the light incident to the organic photoelectric conversion layer. Moreover, the electrical charges which are generated from the green-light organic photoelectric conversion layer 16 and the red-light organic photoelectric conversion layer 21 are accumulated in the SDs 25 and 26, respectively.

However, the color separation characteristics of the photoelectric converters 2, 3, and 4 depends on the optical absorption properties of the organic photoelectric conversion layers 11, 16, and 21, respectively.

Particularly, it is known that, in the photoelectric converter using an organic photoelectric conversion layer, part of exciton that is generated due to absorption of light by an organic semiconductor material forming the organic photoelectric conversion layer is inactivated before charge separation thereof. In the inactivation, there are the cases where thermal radiationless deactivation occurs and emission of light from a lowest excited state occurs. Particularly, in the case of the emission of light, light having a wavelength that is shifted to the longer wavelength side than the wavelength of the absorbed light is emitted from the organic photoelectric conversion layer. Here, in the vertical layered structure in which two or more organic photoelectric conversion layers are stacked in layers in the thickness direction thereof, the light emitted from the organic photoelectric conversion layer serving as the upper layer passes through the other organic photoelectric conversion layer that is located near the above-described organic photoelectric conversion layer, and there is a case where the color separation characteristics becomes degraded.

As an example, a case will be described where, as shown in FIG. 11, green light G only enters through a green-light organic photoelectric conversion layer 116 to a photoelectric conversion device including a vertical layered structure in which the green-light organic photoelectric conversion layer 116 and the red-light organic photoelectric conversion layer 121 are stacked in layers and located adjacent to each other. Firstly, the green-light organic photoelectric conversion layer 116 absorbs the green light G and thereby generates an exciton. Part of the generated exciton is separated due to charge separation, is transferred to an electrode, and is extracted therefrom as a signal E.

On the other hand, the green-light organic photoelectric conversion layer 116 has an exciton whose excitation energy lessens and becomes in a lowest excited state before occurrence of charge separation. This exciton is inactivated by light emission. Red light R₀ that is generated by light emission reaches the near red-light organic photoelectric conversion layer 121 while being unmodified, and the red light is detected as a red light signal. Here, since the red light is not incident to the photoelectric conversion device, the signal obtained by detection of the red light becomes an erroneous signal, and the signal makes the function of the photoelectric conversion device degraded.

Particularly, with reference to FIG. 11, the case is described as an example where the green light enters through the green-light organic photoelectric conversion layer to the vertical layered body in which the green-light organic photoelectric conversion layer 116 and the red-light organic photoelectric conversion layer 121 are stacked in layers. However, even in the case where the green light enters thereinto through the red-light organic photoelectric conversion layer 121 thereto, the same action as the above-mentioned action occurs.

That is, the green light that enters to the vertical layered body through the red-light organic photoelectric conversion layer 121 is transmitted through the red-light organic photoelectric conversion layer 121 and is absorbed by the green-light organic photoelectric conversion layer 116. Furthermore, since the red light R₀ generated in the green-light organic photoelectric conversion layer 116 is also scattered in the directions other than the incident direction of the green light, the red light R₀ reaches the near red-light organic photoelectric conversion layer 121, and red light R₀ is detected as a red light signal.

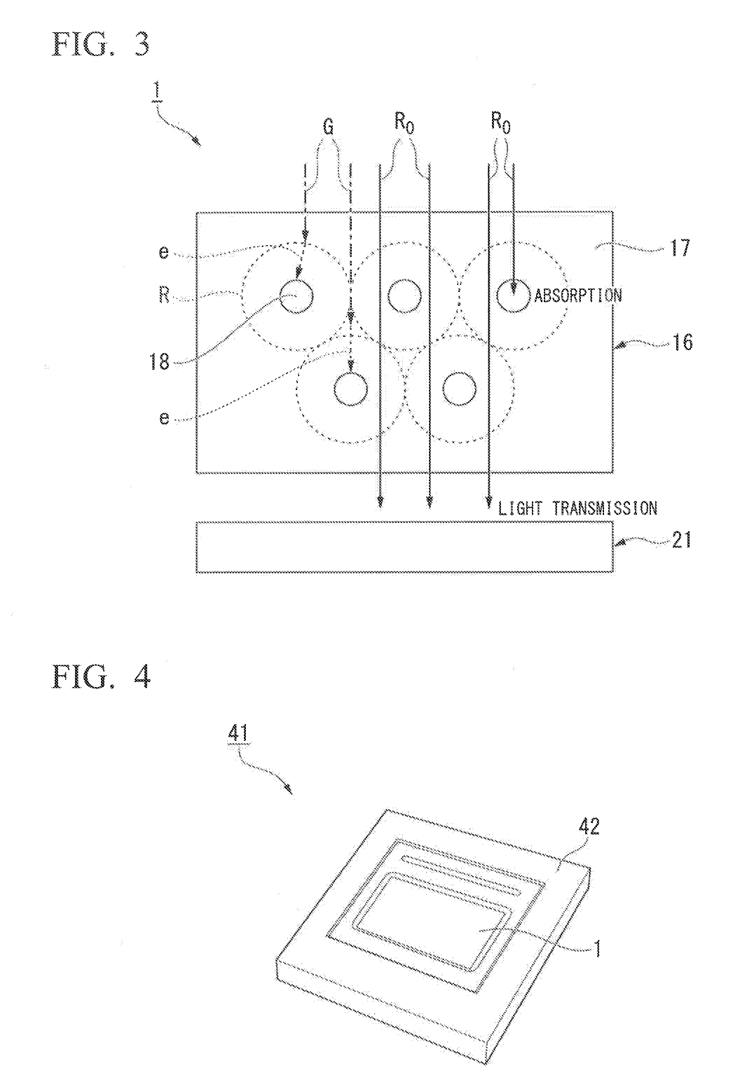

In FIGS. 2 and 3, the green-light organic photoelectric conversion layer 16 and the red-light organic photoelectric conversion layer 21 of the solid-state image sensing device 1 according to the embodiment are only shown.

As shown in FIG. 2, in the solid-state image sensing device 1 according to the embodiment, the second organic dye 18 is present in the green-light organic photoelectric conversion layer 16. When green light enters through the green-light organic photoelectric conversion layer 16 to the solid-state image sensing device 1, the green-light organic photoelectric conversion layer 16 absorbs the green light, an exciton is generated therefrom. Thereafter, the generated exciton is categorized into two excitons, one of the excitons is separated due to charge separation, is transferred to an electrode, and is extracted therefrom as a signal E, and the other of the excitons whose energy lessens to be in a lowest excited state is inactivated by light emission.

Here, in the solid-state image sensing device 1 according to the embodiment, since the exciton gives the excitation energy thereof to the second organic dye 18 before the exciton emits red light and the exciton is inactivated, emission of red light does not occur. After that, the second organic dye 18 that receives the excitation energy and is thereby in an excitation state emits light IR in an infrared region or is inactivated by thermal vibration.

According to the solid-state image sensing device 1 according to the embodiment, since the red light does not reach the near red-light organic photoelectric conversion layer 21, an erroneous signal also does not occur, and it is possible to improve the color separation characteristics while reducing color mixture.

Particularly, with reference to FIG. 2, the case is described as an example where the green light enters through the green-light organic photoelectric conversion layer 16 to the vertical layered body in which the green-light organic photoelectric conversion layer 16 and the red-light organic photoelectric conversion layer 21 are stacked in layers. However, even in the case where the green light enters thereinto through the red-light organic photoelectric conversion layer 21, the same action as the above-mentioned action occurs.

Additionally, the energy difference of the green-light organic semiconductor material 17 between the lowest excited state and the ground state often corresponds to a wavelength of a red region, and the second organic dye 18 that is added to the green-light organic semiconductor material in order to absorb the energy often absorbs the red light.

Here, the case will be described where green light and red light simultaneously enter to the solid-state image sensing device 1 according to the embodiment.

Regarding the green light G that is incident to the green-light organic photoelectric conversion layer 16 shown in FIG. 3, photoelectric conversion is carried out in the green-light organic photoelectric conversion layer 16 as described above, and red light is simultaneously prevented from being emitted therefrom.

On the other hand, regarding the red light R₀, since the second organic dye 18 that absorbs the red light exists, part of the red light is absorbed during transmission of the red light through the green-light organic photoelectric conversion layer 16. However, since the concentration thereof is extremely low, most of the red light is not absorbed by the second organic dye and the red light reaches the red-light organic photoelectric conversion layer 21. The reason for this is that the excitation energy is transferable in a large radius range of approximately 10 nm and, in contrast, absorption of light only occurs at substantially the molecular radius of the organic dye.

The concentration of the second organic dye 18 which sufficiently receives the excitation energy generated from the green-light organic semiconductor material 17 is significantly low as compared with the concentration that effects the transmittance even in the case of absorbing the red light R₀. In the case where the radius at which energy is transferable represents R (m), the required concentration of the second organic dye 18 for preventing the red light from being emitted is 0.75/(N_{A}·R³) (mol/m³). Moreover, the radius R at which energy is transferable varies depending on a photoelectric conversion material and an organic dye.

Particularly, in FIG. 3, in the case where the radius R at which energy is transferable is, for example, 10 nm, the required mol concentration of the second organic dye 18 is 4×10⁻⁴ mol/dm³. Furthermore, in the case where the molar absorptivity of the second organic dye 18 is 3×10⁴ dm³/mol cm and thickness of the green-light organic photoelectric conversion layer is 100 nm, the transmittance of the red light R₀ is 99.97%, it is possible to say that, even in the case of absorbing part of the incident red light R₀, the amount of loss thereof is slight.

Particularly, with reference to FIG. 3, the case is described as an example where the green light and the red light are simultaneously enter through the green-light organic photoelectric conversion layer 16 to the vertical layered body in which the green-light organic photoelectric conversion layer 16 and the red-light organic photoelectric conversion layer 21 are stacked in layers. However, regarding the incident green light, in the case where the green light and the red light simultaneously enter thereto through the red-light organic photoelectric conversion layer 21, the same action as the above-mentioned action occurs. That is, in the green-light organic photoelectric conversion layer 16, since the exciton gives the excitation energy thereof to the second organic dye 18 before the exciton emits red light and the exciton is inactivated, emission of red light does not occur.

On the other hand, in the case where the green light and the red light simultaneously enter to the red-light organic photoelectric conversion layer 21, since all of the incident red light is photoelectrically converted into power by the red-light organic photoelectric conversion layer 21, the incident red light is not absorbed by the second organic dye 18 in the green-light organic photoelectric conversion layer 16.

Moreover, with reference to FIGS. 2 and 3, the case is described as an example where the green light and the red light are simultaneously enter to the solid-state image sensing device 1 according to the embodiment; however, the concentration of the first organic dye 13 and the effect due to the first organic dye in the case where blue light and green light simultaneously enter thereto are the same as the above-mentioned embodiment.

The solid-state image sensing device 1 according to the embodiment includes the photoelectric converters 2, 3, and 4 which are stacked in layers in the thickness direction and are provided with the organic photoelectric conversion layers 11, 16, and 21, respectively. The organic photoelectric conversion layers 11, 16, and 21 selectively absorb three primary colors of light consisting of blue light, green light, and red light which are different from each other, respectively. According to the configuration of the solid-state image sensing device 1 according to the embodiment, since the incident light can be color-separated into the above-described colors and it is possible to photoelectrically convert the incident light into power, it is possible to effectively utilize 100% of three primary colors of light in principle, and it is possible to increase the effective imaging region of each pixel to be substantially 100%.

Furthermore, in the solid-state image sensing device 1 according to the embodiment, it is not necessary to provide a color separation prism or a color filter which are required for carrying out color imaging in conventional image-sensing devices, and it is possible to realize a downsized and lightweight solid-state image sensing device.

Since the solid-state image sensing device 1 according to the embodiment is configured so that the blue-light organic photoelectric conversion layer 11 includes the first organic dye 13, the blue-light organic photoelectric conversion layer 11 absorbs blue light and photoelectrically converts the light into power, the exciton gives the excitation energy thereof to the first organic dye 13 before the exciton emits green light and the exciton is inactivated, and emission of green light does not occur. Thereafter, the first organic dye 13, which receives the excitation energy and is thereby in an excitation state, slightly emits red light or is inactivated by thermal vibration. According to the solid-state image sensing device 1 according to the embodiment, since the green light does not reach the near green-light organic photoelectric conversion layer 16, an erroneous signal also does not occur, and it is possible to improve the color separation characteristics while reducing color mixture.

Particularly, it is conceivable that, since the additive amount of the first organic dye 13 to the blue-light organic photoelectric conversion layer 11 is low, the emission of red light from the first organic dye 13 does not effect the red-light organic photoelectric conversion layer 21. On the other hand, in order to prevent the influence of the emission of red light due to the aforementioned first organic dye 13, an organic dye that can absorb red light may be additionally introduced into the blue-light organic photoelectric conversion layer 11. Moreover, as the first organic dye 13 that is to be introduced into the blue-light organic photoelectric conversion layer 11, it is preferable to select an organic dye having a low level of light emission efficiency.

Since the solid-state image sensing device 1 according to the embodiment is configured so that the green-light organic photoelectric conversion layer 16 includes the second organic dye 18, the green-light organic photoelectric conversion layer 16 absorbs green light and photoelectrically converts the light into power, the exciton gives the excitation energy thereof to the second organic dye 18 before the exciton emits red light and the exciton is inactivated, and emission of red light does not occur. After that, the second organic dye 18 that receives the excitation energy and is thereby in an excitation state emits light IR in an infrared region or is inactivated by thermal vibration. According to the solid-state image sensing device 1 according to the embodiment, since the red light does not reach the near red-light organic photoelectric conversion layer 21, an erroneous signal also does not occur, and it is possible to improve the color separation characteristics while reducing color mixture.

The configuration of the solid-state image sensing device 1 according to the embodiment is an example.

In the first embodiment, as an example of the solid-state image sensing device 1, a backside-illumination solid-state image sensing device is described. However, the above-described configuration is applicable to a frontside-illumination solid-state image sensing device. In this case in which the configuration is applied to the frontside-illumination solid-state image sensing device, it is possible to obtain the same effect as that of the solid-state image sensing device 1 according to the first embodiment.

Additionally, the solid-state image sensing device 1 including the red-light photoelectric converter 4, the green-light photoelectric converter 3, and the blue-light photoelectric converter 2 which are stacked on the substrate 5 in layers in this order is described as an example in the first embodiment. However, a three-layered configuration in which photoelectric converters are stacked in layers in an order other than the above-described order is applicable to the solid-state image sensing device. In this case in which the photoelectric converters that are stacked in layers in the other order described above is applied to the solid-state image sensing device, it is possible to obtain the same effect as that of the solid-state image sensing device 1 according to the first embodiment.

Particularly, in this case of applying, to the solid-state image sensing device, the three-layered configuration in which the blue-light photoelectric converter 2, the green-light photoelectric converter 3, and the red-light photoelectric converter 4 which are stacked on the substrate in layers in this order, it is possible to prevent absorption of incident light due to the first organic dye 13 and the second organic dye 18.

Moreover, the solid-state image sensing device 1 including the first organic dye 13 dispersed in the blue-light organic photoelectric conversion layer 11 and the second organic dye 18 dispersed in the green-light organic photoelectric conversion layer 16 is described as an example in the first embodiment. However, any one of the organic photoelectric conversion layers in which an organic dye is dispersed may be used in the solid-state image sensing device.

FIG. 4 is a perspective view showing an example of a CMOS image sensor 41 to which the solid-state image sensing device 1 according to the first embodiment is applied. The CMOS image sensor 41 is a Full-HD (1080p) CMOS image sensor. The CMOS image sensor 41 includes the solid-state image sensing device 1 and a molded resin 42.

The molded resin 42 is provided so as to cover the portions other than a light-receiving face of the solid-state image sensing device 1. As a result of integrating the solid-state image sensing device 1 and the molded resin 42 into one body, it is possible to protect the solid-state image sensing device 1 from moisture, contaminant, and stress applied from the outside of the solid-state image sensing device.

The CMOS image sensor 41 is used in an imaging device, for example, digital cameras, mobile terminals such as portable telephones (including smartphones), monitoring cameras, web cameras utilizing the internet, and the like.

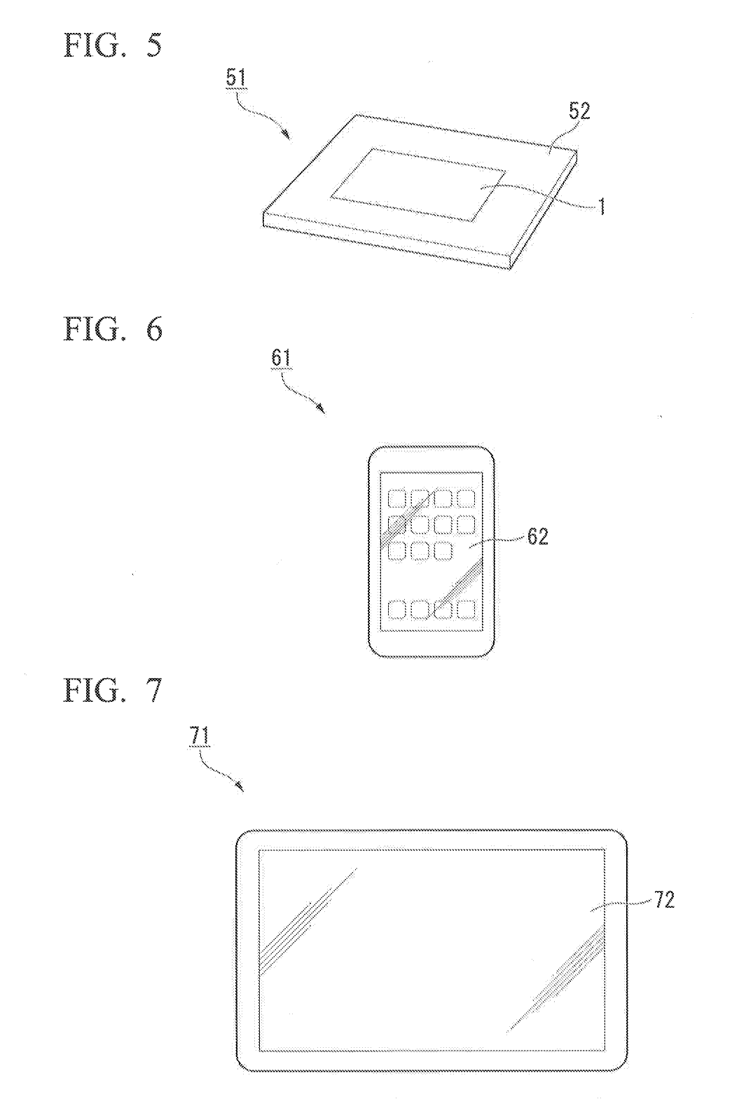

FIG. 5 is a perspective view showing another example of a CMOS image sensor to which the solid-state image sensing device according to the first embodiment is applied. The CMOS image sensor 51 is a VGA CMOS image sensor. The CMOS image sensor 51 includes the solid-state image sensing device 1 and a molded resin 52.

The molded resin 52 is provided so as to cover the portions other than a light-receiving face of the solid-state image sensing device 1. As a result of integrating the solid-state image sensing device 1 and the molded resin 52 into one body, it is possible to protect the solid-state image sensing device 1 from moisture, contaminant, and stress applied from the outside of the solid-state image sensing device.

The CMOS image sensor 51 is used in an imaging device, for example, digital cameras, mobile terminals such as portable telephones (including smartphones), monitoring cameras, web cameras utilizing the internet, and the like.

FIG. 6 is a plan view showing a smartphone 61 provided with a camera on which the above-mentioned CMOS image sensor 41 or CMOS image sensor 51 is mounted. The smartphone 61 includes a camera (not shown in the figure) and a touch panel 62. In the case where the camera is provided at, for example, the upper front side of the smartphone 61, it is possible to image-capture the front side of the smartphone 61. Furthermore, the touch panel 62 is provided at the center of the smartphone and can display the image that is image-captured by the camera.

FIG. 7 is a plan view showing a tablet terminal 71 provided with a camera on which the above-mentioned CMOS image sensor 41 or CMOS image sensor 51 is mounted. The tablet terminal 71 includes a camera (not shown in the figure) and a touch panel 72. In the case where the camera is provided at, for example, the upper front side of the tablet terminal 71, it is possible to image-capture the front side of the tablet terminal 71. Furthermore, the touch panel 72 is provided at the center of the camera and can display the image that is image-captured by the camera.

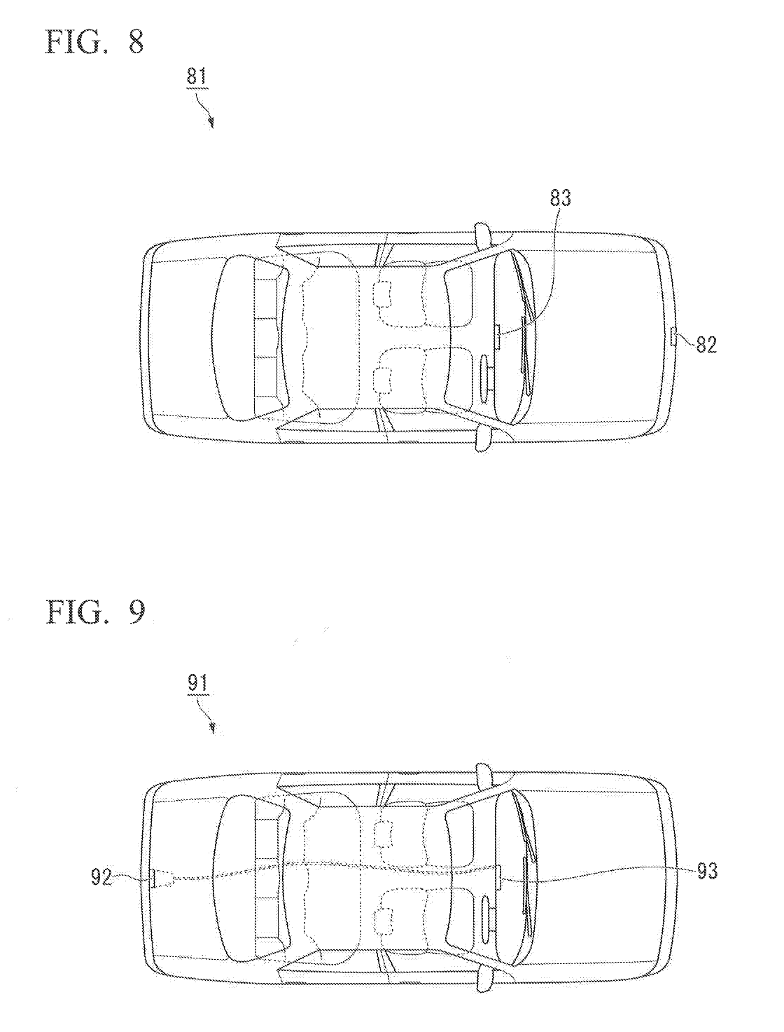

FIG. 8 is a perspective view showing an example of an automobile 81 provided with a camera 82 on which the above-mentioned CMOS image sensor 41 or CMOS image sensor 51 is mounted. The automobile 81 is provided with the camera 82 and a display 83. The camera 82 is provided on the front end of the automobile 81 and can image-capture the front side of the automobile 81. Moreover, the display 83 is provided in front of driver's seat front of the automobile 81 and can display the image that is image-captured by the camera 82. The driver can check the image that is image-captured by the camera 82 and displayed on the display 83. For example, the driver can check blind spots of the automobile when the driver parks the automobile.

FIG. 9 is a plan view showing another example of an automobile 91 provided with a camera 92 on which the above-mentioned CMOS image sensor 41 or CMOS image sensor 51 is mounted. The automobile 91 is provided with the camera 92 and a display 93. The camera 92 is provided on the rearward end of the automobile 91 and can image-capture the rear side of the automobile 91. Moreover, the display 93 is provided in front of driver's seat front of the automobile 91 and can display the image that is image-captured by the camera 92. The driver can check the image that is image-captured by the camera 92 and displayed on the display 93 and can thereby check the rear side of the automobile 91.

### Second Embodiment

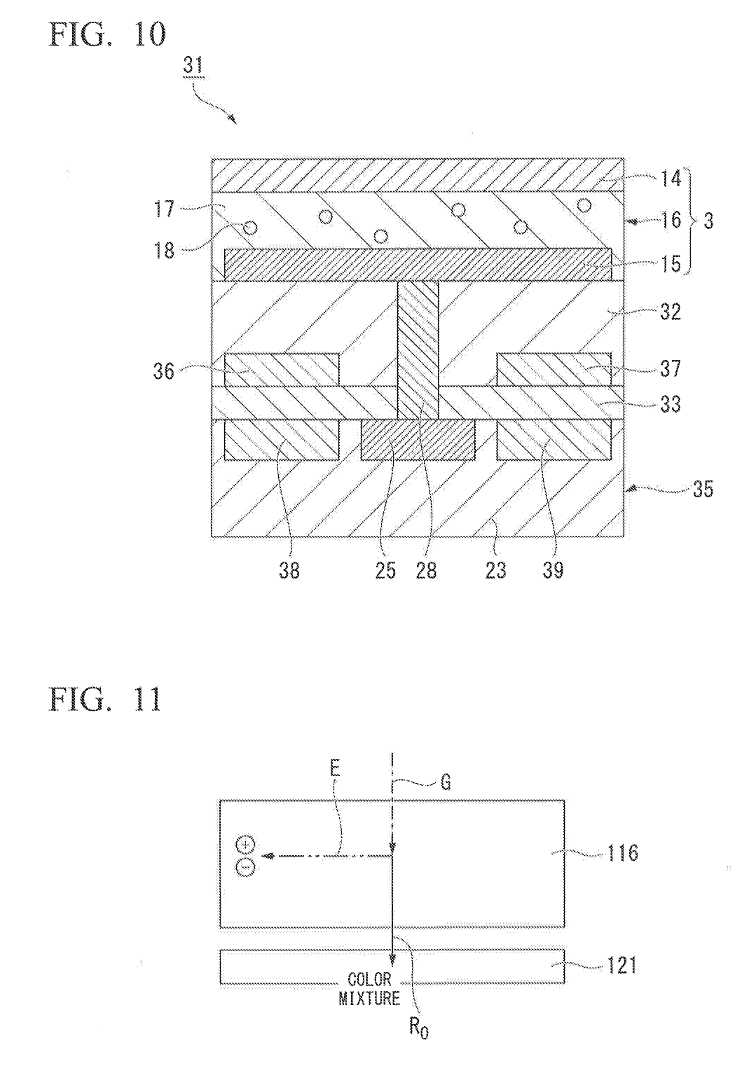

FIG. 10 is a cross-sectional view showing a major part of a solid-state image sensing device according to a second embodiment.

As shown in FIG. 10, a solid-state image sensing device 31 according to the second embodiment includes a substrate 35, color filters 36 and 37 (two color filters), the photodiodes 38 and 39 serving as a photoelectric converter, and the green-light photoelectric converter 3. The solid-state image sensing device 31 according to the embodiment is common to the solid-state image sensing device 1 according to the first embodiment in that both the solid-state image sensing devices include the green-light photoelectric converter 3. The solid-state image sensing device 31 has the structure that is different from that of the solid-state image sensing device 1 in that the solid-state image sensing device 31 includes the color filters 36 and 37 and the photodiodes 38 and 39. Therefore, identical reference numerals are used for the elements which are common to those of the solid-state image sensing device 1 according to the first embodiment, and explanations thereof are omitted here.

The substrate 35 includes the semiconductor substrate 23, the photodiodes 38 and 39 serving as a photoelectric converter, and the SD 25.

The photodiode 38 is provided inside the semiconductor substrate 23 that is located under the color filter 36. The photodiode 38 is configured to include: a first impurity region (not shown in the figure) that is exposed at the top surface of the semiconductor substrate 23; and a second impurity diffusion region (not shown in the figure) connected to the upper of the first impurity diffusion region.

As the first impurity diffusion region, for example, a high concentration P-type impurity diffusion region can be used. In this case, as the second impurity diffusion region, a high concentration N-type impurity diffusion region can be used.

The photodiode 38 is disposed so as to face the color filter 36 so that an insulating layer 33 provided on the semiconductor substrate 23 is sandwiched between the photodiode 38 and the color filter 36. For example, in the case where the color filter 36 is a filter that allows red light to be transmitted therethrough, when the photodiode 38 receives red light, the photodiode photoelectrically converts the red light into power, and generates an electrical charge corresponding to the red light.

The photodiode 39 is provided inside the semiconductor substrate 23 that is located under the color filter 37. The photodiode 39 has the same configuration as that of the aforementioned photodiode 38.

The photodiode 39 is disposed so as to face the color filter 37 so that the insulating layer 33 provided on the semiconductor substrate 23 is sandwiched between the photodiode 39 and the color filter 37. For example, in the case where the color filter 37 is a filter that allows blue light to be transmitted therethrough, when the photodiode 39 receives blue light, the photodiode photoelectrically converts the blue light into power, and generates an electrical charge corresponding to the blue light.

Insulating layers 32 and 33 are insulating films provided between the substrate and the green-light photoelectric converter 3. As long as the insulating films are made of a material having optical transparency, it is not particularly limited to this.

In the insulating layer 32, the color filters 36 and 37 are provided near the insulating layer 33. The color filters 36 and 37 allows light, which has a color (i.e., red or blue) different from green that is to be photoelectrically converted by the green-light organic photoelectric conversion layer 16, to be transmitted therethrough. For example, a color filter that allows red light to be transmitted therethrough can be used as the color filter 36, and a color filter that allows blue light to be transmitted therethrough can be used as the color filter 37.

Next, an action of the solid-state image sensing device 31 according to the embodiment will be described.

Regarding light incident to the solid-state image sensing device 31 according to the embodiment, the green-light photoelectric converter 3 absorbs green light and allows blue light and red light to be transmitted therethrough. Subsequently, the green-light organic photoelectric conversion layer 16 absorbs the green light and photoelectrically converts the light into power, and an electrical charge is generated therefrom in the green-light photoelectric converter 3. At this time, the amount of the generated electrical charge varies depending on the intensity of the light incident to the organic photoelectric conversion layer. The generated electrical charge is accumulated in the SD 25.

Next, regarding the light that is passed through the green-light organic photoelectric conversion layer 16, red light passes through the color filter 36. Furthermore, when the photodiode 38 receives the transmitted red light, the photodiode photoelectrically converts the red light into power and generates an electrical charge corresponding to the red light.

Next, regarding the light that is passed through the green-light organic photoelectric conversion layer 16, blue light passes through the color filter 37. Furthermore, when the photodiode 39 receives the transmitted blue light, the photodiode photoelectrically converts the blue light into power and generates an electrical charge corresponding to the blue light.

After that, an electrical charge that is accumulated in the SD 25 and the photodiodes 38 and 39 serving as a photoelectric conversion device is transmitted to floating diffusion (not shown in the figure). The electrical charge that is transmitted to the floating diffusion is converted into an electrical signal, and is transmitted to a peripheral circuit (not shown in the figure) through a multi-layer interconnection or the like. As stated above, the pixels of the solid-state image sensing device 31 according to the embodiment can independently detect lights having wavelength-bands of three kinds of colors.

In the solid-state image sensing device 31 according to the second embodiment, since the green-light organic photoelectric conversion layer 16 is configured to include the second organic dye 18 which is similar to that of the solid-state image sensing device 1 according to the first embodiment, the green-light organic photoelectric conversion layer absorbs the green light and photoelectrically converts the light into power, the exciton gives the excitation energy thereof to the second organic dye 18 before the exciton emits red light, the exciton is inactivated, and emission of red light does not occur.

Particularly, in the solid-state image sensing device 31 according to the embodiment, the red light emitted from the green-light organic photoelectric conversion layer 16 does not reach the photodiode 38 (serving as a photoelectric conversion device corresponding to red light), and an erroneous signal also does not occur. As a result, it is possible to improve the color separation characteristics while reducing color mixture.

Here, as described above, the wavelength of the red light is longest and the wavelength of the blue light is shortest in the green light, the red light. Additionally, the wavelength of the green light is located between the wavelength of the red light and the wavelength of the blue light.

For this reason, in the solid-state image sensing device 31 according to the second embodiment, as a result of: providing, near the light incident side (the portion to which light is to be incident), the green-light photoelectric converter 3 including the green-light organic photoelectric conversion layer 16; and providing, under the green-light photoelectric converter, the color filters 36 and 37 that allow the red light and blue light to be transmitted therethrough, respectively, it is possible to carry out color separation of the red light from the blue light with a high level of accuracy.

The configuration of the solid-state image sensing device 31 according to the embodiment is an example, and it is not limited to this.

In the second embodiment, in the case is described where the green-light organic photoelectric conversion layer 16 including the second organic dye 18 is used as an organic photoelectric conversion layer that is provide near the light incident side, a configuration in which the blue-light organic photoelectric conversion layer 11 including the first organic dye 13 is used therefor may be adopted. In this case, the color filter 37 is replaced with a filter that allows green light to be transmitted therethrough. According to the foregoing configuration, it is possible to prevent occurrence of color mixture due to green light.

The configuration in which one kind of or three kinds of photoelectric converters including an organic photoelectric conversion layer are stacked in layers is adopted in the above-described embodiments. However, a configuration in which two kinds of photoelectric converters are stacked in layers may be adopted. That is, in this case, two or more photoelectric converters, each of which includes an organic photoelectric conversion layer, are provided in the solid-state image sensing device; the organic photoelectric conversion layers of the photoelectric converters selectively absorb lights which are selected from three primary colors of light consisting of blue light, green light, and red light and are different from each other; and it is only necessary that one or more organic photoelectric conversion layers include an organic dye.

According to at least one of the above-described embodiments, the solid-state image sensing device is configured to include at least one organic photoelectric conversion layer including the organic dye that receives the excitation energy of an exciton before the exciton emits light and causes the exciton to be inactivated. Specifically, since the green-light organic photoelectric conversion layer 16 is configured to include the green-light organic semiconductor material 17 and the second organic dye 18, the green-light organic semiconductor material 17 absorbs green light and photoelectrically converts the green light into power. Moreover, in the green-light organic photoelectric conversion layer 16, since the exciton gives the excitation energy thereof to the second organic dye 18 before the exciton emits red light and the exciton is inactivated, emission of red light does not occur. Consequently, the red light due to light emission from the green-light organic photoelectric conversion layer 16 does not reach a red-light photoelectric conversion device that is located near the green-light organic photoelectric conversion layer, and an erroneous signal does not occur. Because of this, it is possible to improve the color separation characteristics while reducing color mixture due to red light.

Moreover, in the configuration using the blue-light organic photoelectric conversion layer 11 including the first organic dye 13 instead of the green-light organic photoelectric conversion layer 16, it is possible to improve the color separation characteristics while reducing color mixture due to green light.

### Examples

Hereinafter, Example 1 will be described.

The organic photoelectric conversion film of Example 1 has the same configuration as that of the green-light organic photoelectric conversion layer 16 according to the first and second embodiments.

The organic photoelectric conversion film of Example 1 was produced under the following conditions.

A solution was prepared by adding, to a chlorobenzene solution containing polyvinyl carbazole used as a host material and rhodamine 6G used as a green-light organic semiconductor material, a small amount of 2,4-bis(4-(diethylamino)-2-hydroxyphenyl) squaraine used as an organic dye which absorbs the energy corresponding to that of red light. Next, the above-mentioned prepared solution was applied on a quartz substrate by spin coating, and the organic photoelectric conversion film of Example 1 was formed.

Hereinafter, Comparative Example 1 will be described.

The organic photoelectric conversion film of Comparative Example 1 is different from the organic photoelectric conversion film of Example 1 in that Comparative Example 1 does not include the organic dye (2,4-bis(4-(diethylamino)-2-hydroxyphenyl) squaraine) which absorbs the energy corresponding to that of red light. The other compositions of the organic photoelectric conversion film of Comparative Example 1 were the same as those of Example 1.

The organic photoelectric conversion film of Comparative Example 1 was produced under the following conditions.

A chlorobenzene solution containing polyvinyl carbazole used as a host material and rhodamine 6G used as a green-light organic semiconductor material was prepared. Next, the above-mentioned prepared chlorobenzene solution was applied on a quartz substrate by spin coating, and the organic photoelectric conversion film of Comparative Example 1 was formed.

After that, regarding the organic photoelectric conversion films of Example 1 and Comparative Example 1 which were formed on the aforementioned respective quartz substrates, the respective transmission spectrums thereof and the respective emission spectrums thereof were measured, comparison and evaluation thereof was carried out.

As a result of comparing the transmission spectrums of the organic photoelectric conversion films (including quartz substrate) of Example 1 and Comparative Example 1, the both transmittance ratios of red light (650 nm) to the transmittance of green light (540 nm) were 1.3.

Consequently, it can be determined that reduction in transmittance hardly occurs as a result of adding the organic dye that absorbs the energy corresponding to that of red light to the green-light organic photoelectric conversion film.

In contrast, as a result of comparing the emission spectrums of the organic photoelectric conversion films (including quartz substrate) of Example 1 and Comparative Example 1, the emission intensity of Example 1 at a wavelength of near 610 nm due to rhodamine 6G was substantially reduced by a half as compared with that of Comparative Example 1.

Therefore, it can be determined that the emission intensity of red light can be reduced by a substantially half as a result of adding the organic dye that absorbs the energy corresponding to that of red light to the green-light organic photoelectric conversion film.

From above-mentioned comparison and evaluation of Example 1 and Comparative Example 1, it can be determined that, as a result of adding the organic dye that absorbs the energy corresponding to that of red light to the green-light organic photoelectric conversion film, the emission of light from the green-light organic semiconductor material can be reduced (i.e., color mixture can be prevented) almost without modifying the transmittance characteristics of the green-light organic photoelectric conversion film.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state image sensing device comprising:
an organic photoelectric conversion layer comprising an organic semiconductor material and an organic dye, the organic semiconductor material selectively absorbing light having one of three primary colors of light selected from blue light, green light, and red light, the organic semiconductor material allowing the other two of the three primary colors of light to be transmitted therethrough, the organic dye being dispersed in the organic semiconductor material, the organic dye receiving energy less than excitation energy of the organic semiconductor material.

2. The solid-state image sensing device according to claim 1, wherein
the organic photoelectric conversion layer absorbs all of light having a wavelength corresponding to the excitation energy of the organic semiconductor material, the organic photoelectric conversion layer absorbs some of light having a wavelength corresponding to a lower level of energy than the excitation energy, and the organic photoelectric conversion layer allows remaining light to be transmitted therethrough.

3. The solid-state image sensing device according to claim 1, wherein
a mass content of the organic dye is lower than a mass content of the organic semiconductor material in the organic photoelectric conversion layer.

4. The solid-state image sensing device according to claim 1, wherein
a concentration of the organic dye contained in the organic photoelectric conversion layer is 0.75/(N_{A}·R³) (mol/m³) where an energy transfer radius of the organic semiconductor material is defined as R (m) and Avogadro's constant is defined as N_{A} (mol⁻¹).

5. The solid-state image sensing device according to claim 1, further comprising a photoelectric converter comprising: a pair of electrodes, wherein the pair of electrodes sandwiches the organic photoelectric conversion layer.

6. The solid-state image sensing device according to claim 5, further comprising:
two or more photoelectric converters, each photoelectric converter including the organic photoelectric conversion layer, organic photoelectric conversion layers of the photoelectric converters selectively absorbing lights which are selected from three primary colors of light consisting of blue light, green light, and red light and are different from each other, wherein
one or more organic photoelectric conversion layers include the organic dye.

7. The solid-state image sensing device according to claim 6, wherein
the two or more photoelectric converters are stacked in layers in a thickness direction.
